(19) United States
(12) Patent Application Publication
(10) Pub. No.: US 2012/0306106 A1
(43) Pub. Date: Dec. 6, 2012

(54) SEMICONDUCTOR DEVICE HAVING DUMMY PATTERN AND DESIGN METHOD THEREOF

(75) Inventor: Yorio TAKADA, Tokyo (JP)

(73) Assignee: Elpida Memory, Inc., Tokyo (JP)

(21) Appl. No.: 13/478,211

(22) Filed: May 23, 2012

(30) Foreign Application Priority Data
May 31, 2011 (JP) 2011-122292

(51) Int. Cl. H01L 23/52

(52) U.S. Cl. 257/784; 257/E23.141

(57) ABSTRACT

Disclosed herein is the semiconductor substrate, wiring patterns and dummy patterns. A margin region is formed around the wiring pattern. The dummy region is further formed around the margin region. The dummy patterns are formed in the dummy region. The dummy patterns are arranged along the extending direction of the dummy region. Margin regions and dummy regions are allocated alternately with respect to the wiring pattern.

### BACKGROUND OF THE INVENTION

1. Field of the Invention

The present invention relates to a semiconductor device and its design method, and more particularly to a semiconductor device and its design method that use planarization process based on a chemical mechanical polishing (CMP).

2. Description of Related Art

In the development of semiconductor devices, lithographic optical systems including light sources have recently been advanced and improved in resolution. Such improvements result in more severe specifications on the depth of focus. Meanwhile, miniaturization technology and multilayer wiring technology have been introduced to form complicated projections and depressions (steps) on the surface of a semiconductor device. Such steps make it difficult to process a fine pattern to desired dimensions. CMP techniques have been introduced to solve the problem. CMP is a polishing technology that can simultaneously resolve local steps and global steps formed on the surface of a semiconductor device. CMP can planarize the surface of a semiconductor device so as to meet the specifications on the depth of focus and process a fine pattern with high accuracy. However, CMP has a polishing characteristic extremely sensitive to the pattern density on the surface to be polished. At locations where differences in pattern density are high, CMP causes “dishing and erosion” which deteriorate flatness. There is thus a problem that the specifications on the depth of focus fail to be met.

Patterns for resolving differences in pattern density (hereinafter, referred to as “dummy patterns”) may be arranged aside from electrically contributing patterns (hereinafter, referred to as “wiring patterns”) (see Japanese Patent Application Laid-Open No. 2006-39587. The provision of dummy patterns suppresses problems such as dishing and erosion that occur when CMP is applied.

### SUMMARY

To suppress dishing and erosion effectively, dummy patterns are desirably arranged with margins of a minimum reference value that is greater than or equal to that between a wiring pattern and a dummy pattern, defined by design rules or the like, and does not produce excessive margins.

According to the conventional technology, regions where dummy patterns can be arranged are extracted, and dummy patterns are arranged in the extracted regions as a point of origin at the lower left or at the center. Consequently, dummy patterns are not always arranged with a minimum reference value especially in most important regions near wiring patterns etc.

It is a main object of the present invention to arrange dummy patterns with respect to wiring patterns so that dummy patterns are arranged with margins close to a minimum reference value.

In one embodiment, there is provided a semiconductor device that includes a wiring pattern formed on a wiring region; a dummy pattern formed on a dummy region; and a margin region being free from the wiring pattern and the dummy pattern, the margin region having a substantially constant width between the wiring region and the dummy region.

In another embodiment, there is provided a semiconductor device that includes: a wiring pattern to transfer a signal or to be supplied with a specific voltage and including a first edge and a second edge intersect with the first edge; a plurality of first patterns provided along to the first edge and aligned in a first straight line; a plurality of second patterns provided along to the second edge and aligned in a second straight line; and a third pattern of a regular tetragon formed on an intersection of the first and second straight lines.

In another embodiment, there is provided a design method of a semiconductor device, the method comprising: defining a wiring region on which a wiring pattern is to be formed; defining a margin region around the wiring region; defining a dummy region around the margin region; and arranging a plurality of dummy patterns on the dummy region along an extending direction of the dummy region.

According to the present invention, by allocating a dummy pattern with minimum margin, dishing and erosion is easily suppressed. It makes easier to meet the needs of stable planarization, layout density growth and the severe specification on the depth of focus.

### BRIEF DESCRIPTION OF THE DRAWINGS

The above and other features and advantages of the present invention will be more apparent from the following description of certain preferred embodiments taken in conjunction with the accompanying drawings, in which:

FIG. 1 is a layout diagram showing wiring patterns of a semiconductor device;

FIG. 2 is a layout diagram showing a wiring pattern in the partial region P1;

FIG. 3 is a layout diagram showing a margin region in the partial region P1;

FIG. 4 is a layout diagram showing a dummy region in the partial region P1;

FIG. 5 is a first layout diagram during the generation of dummy patterns in the partial region P1;

FIG. 6 is a second layout diagram during the generation of dummy patterns in the partial region P1;

FIG. 7 is a layout diagram showing dummy patterns;

FIG. 8 is a layout diagram showing a second margin region in the partial region P1;

FIG. 9 is a layout diagram showing a second layer of dummy patterns in the partial region P1;

FIG. 10 is an overall layout diagram of dummy patterns in the partial region P1;

FIG. 11 is a layout diagram showing wiring patterns in the partial region P2;

FIG. 12 is a layout diagram showing margin regions and dummy regions in the partial region P2;

FIG. 13 is a layout diagram showing dummy patterns in the partial region P2;

FIG. 14 is a layout diagram showing wiring patterns, margin regions, and dummy regions in the partial region P3;

FIG. 15 is a layout diagram showing dummy patterns in the partial region P3; and

FIG. 16 is a flowchart showing the procedure for designing dummy patterns.

### DETAILED DESCRIPTION OF THE EMBODIMENTS

Preferred embodiments of the present invention will be explained below in detail with reference to the accompanying drawings.

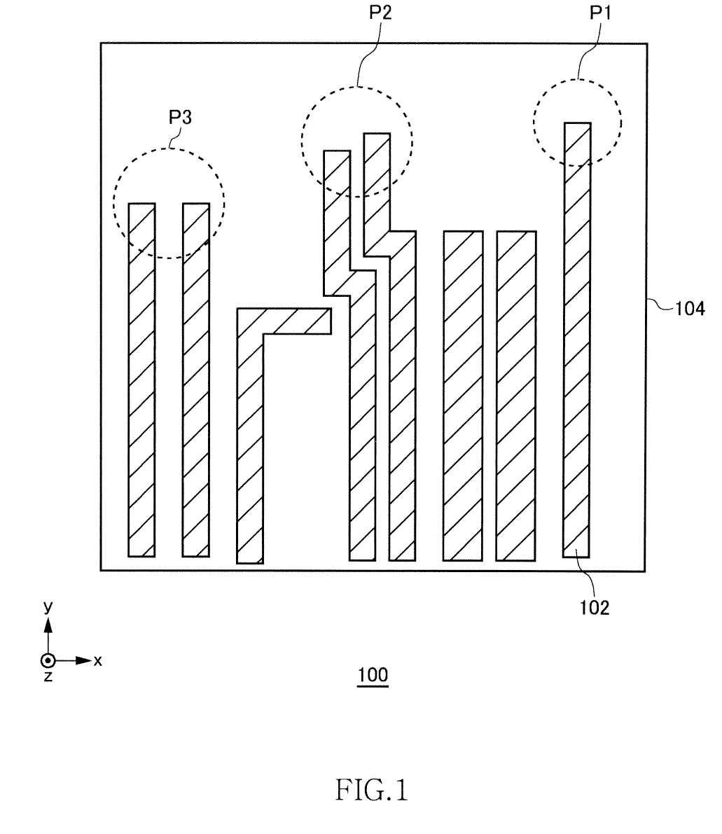

FIG. 1 is a layout diagram showing wiring patterns 102 of a semiconductor device 100. In the diagram, an x-axis is set to be rightward, a y-axis upward, and a z-axis to the near side of the plane of the diagram. The direction of the z-axis corresponds to a thickness direction. A plurality of wiring patterns 102 are laid out on the xy plane of a semiconductor substrate 104. The wiring patterns 102 constitute metal wiring for connecting various types of electronic elements such as transistors and capacitors formed on the semiconductor device 100. The wiring patterns 102 are once buried in an interlayer insulating film before the xy plane is planarized by a CMP process.

Regions where the wiring patterns 102 are formed will be referred to as “wiring regions.” Regions where no wiring pattern 102 is formed will be referred to as “non-wiring regions.” For stable CMP planarization, the non-wiring regions are provided with metal wiring called dummy patterns. The provision of dummy patterns makes the wiring distribution in the directions of the xy plane uniform. Dummy patterns are desirably arranged with constant margins (constant spaces) and in a uniform pattern. The present embodiment proposes a method for arranging dummy patterns in a non-wiring region. The dummy patterns may be electrically in a floating state.

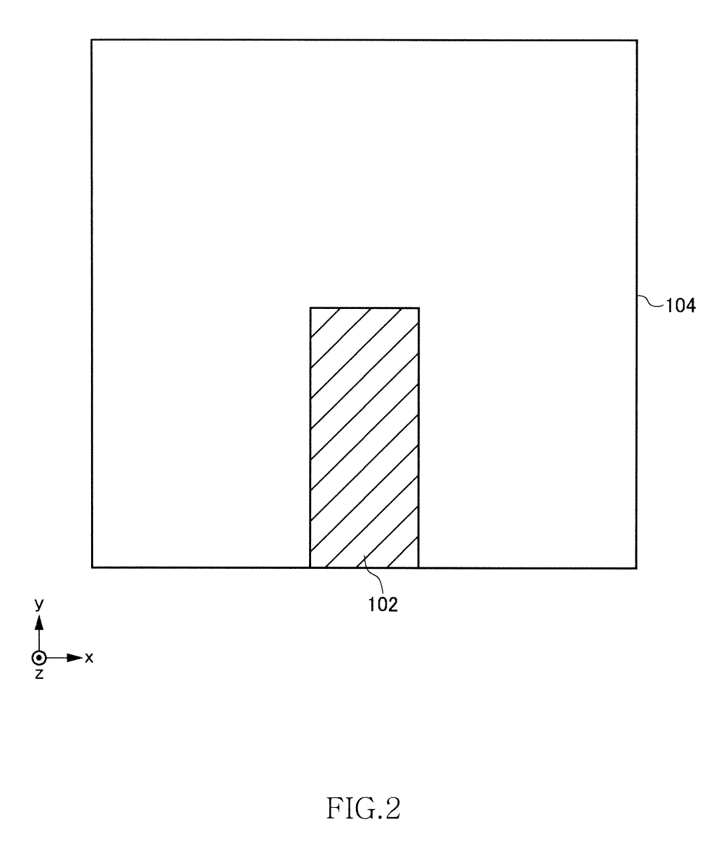

Before actual manufacturing of the semiconductor device 100, the layout of the wiring patterns 102 and dummy patterns on the semiconductor substrate 104 is designed by using design software (semiconductor device design support program). In the present embodiment, the layout of dummy patterns is determined according to a predetermined algorithm with respect to the wiring patterns 102. Referring to FIG. 2 and subsequent drawings, methods for arranging dummy patterns in the vicinities of respective partial regions P1, P2, and P3 shown in FIG. 1 will be described. A basic idea will initially be described in conjunction with the partial region P1. Applicable ideas will be described in conjunction with the partial regions P2 and P3.

FIG. 2 is a layout diagram showing a wiring pattern 102 in the partial region P1. In the present embodiment, dummy patterns are arranged in a radial pattern around the outer edges of the wiring pattern 102. FIG. 2 is an enlarged view of an end of the wiring pattern 102.

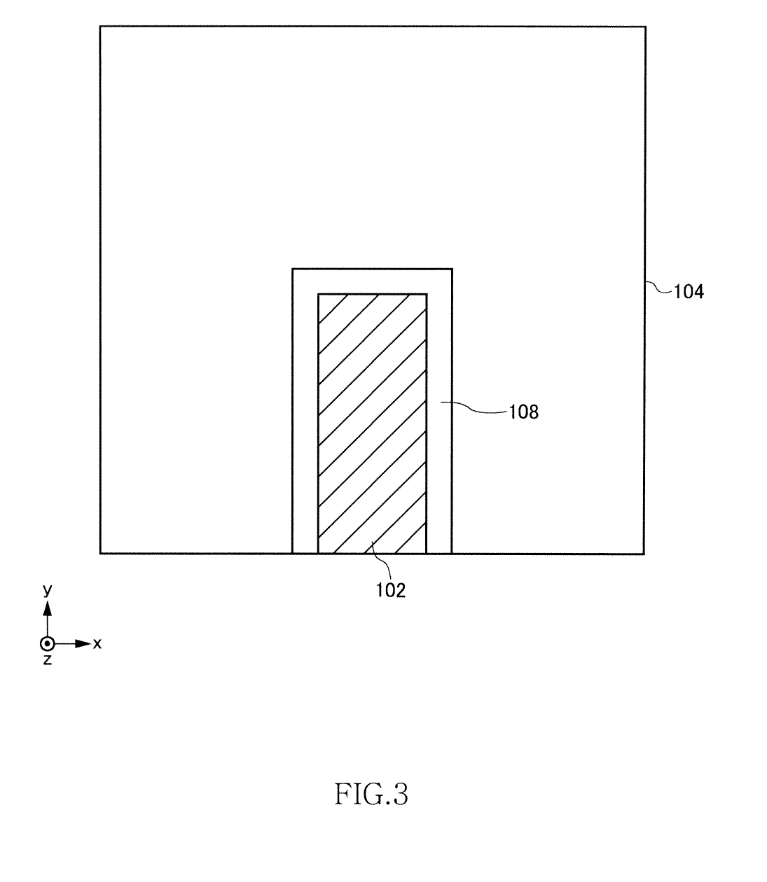

FIG. 3 is a layout diagram showing a margin region 108 in the partial region P1. For dummy patterns, a margin region 108 having a predetermined width is provided so as to surround the wiring pattern 102 (wiring region). The wiring region and the layout region of the wiring pattern 102 may be exactly the same. At least the wiring region may be set to be a region that includes the wiring pattern 102.

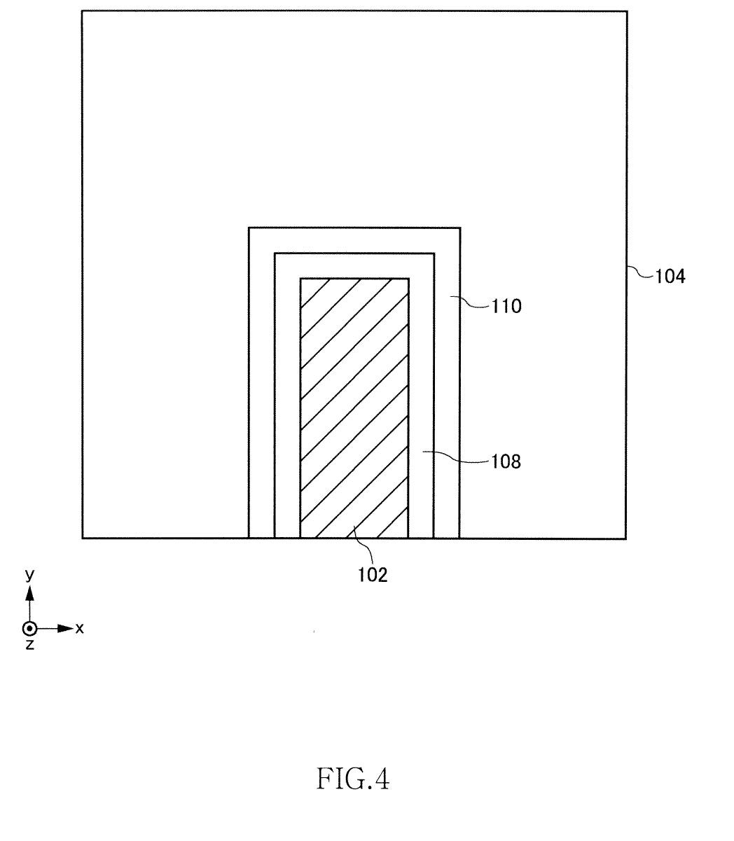

FIG. 4 is a layout diagram showing a dummy region 110 in the partial region P1. A dummy region 110 having a predetermined width is set so as to surround the margin region

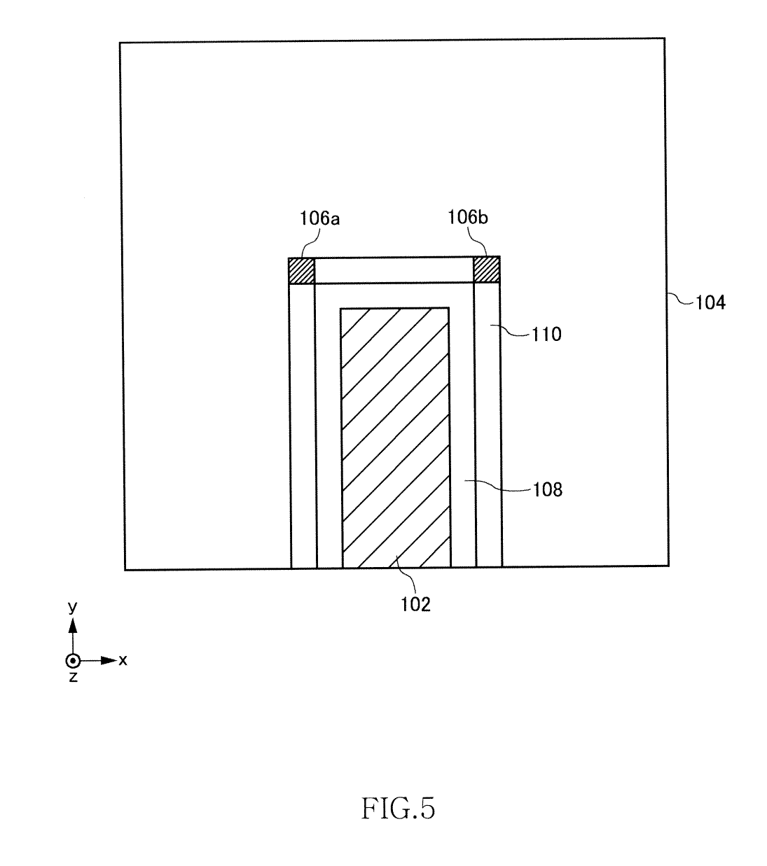

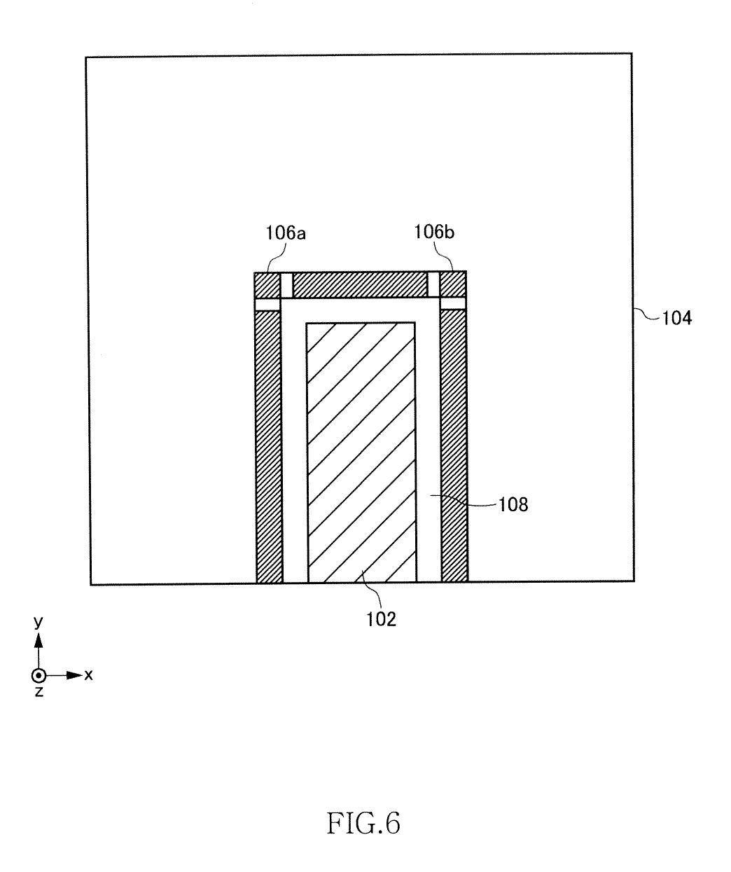

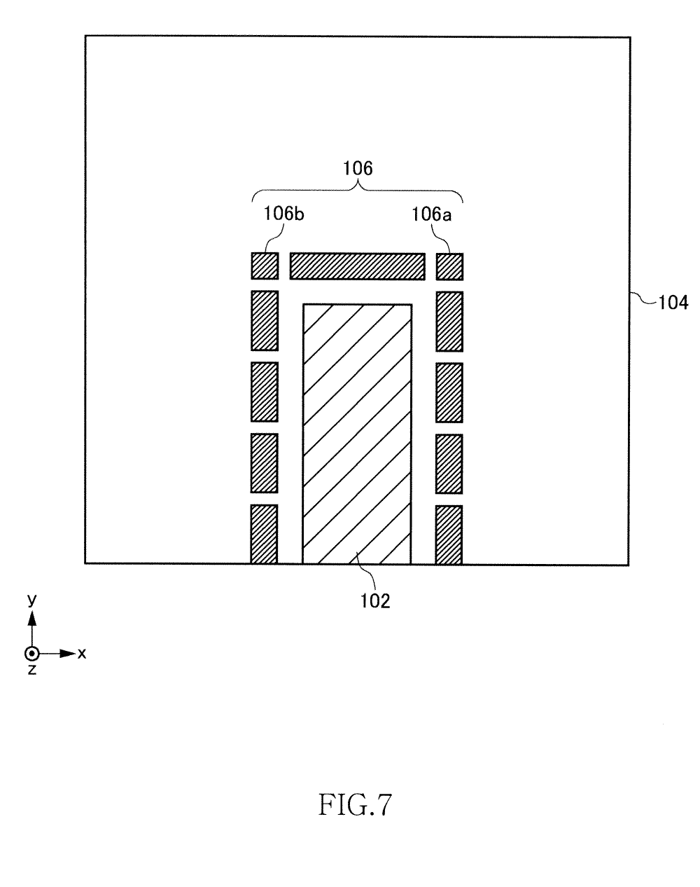

FIGS. 5 and 6 are layout diagrams during the generation of dummy patterns 106 in the partial region P1. FIG. 7 is a layout diagram after the generation of the dummy patterns 106. The dummy patterns 106 are arranged in the dummy region 110. Square dummy patterns 106a and 106b are initially arranged at the corners of the dummy region 110 (FIG. 5). Regions are set with a necessary margin from the dummy patterns 106a and 106b, and dummy patterns are further set in the regions (FIG. 6).

Next, the areas of the dummy patterns other than the dummy patterns 106a and 106b are calculated. Large-area figures that do not meet an area criterion defined by design rules or the like are subjected to division processing until the area criterion is met. Small-area figures that do not meet the area criterion are subjected to widening processing. In the widening processing, the figures to be widened and the dummy region 110 can be ORed to control the widening in the directions of the x-axis and the y-axis. Consequently, a plurality of types of square and rectangular dummy patterns 106 are arranged so as to surround the wiring pattern 102 (FIG. 7).

When actually manufacturing the semiconductor device 100, wiring patterns 102 and dummy patterns 106 are formed by the same process. Wiring patterns 102 and dummy patterns 106 are often made of the same material.

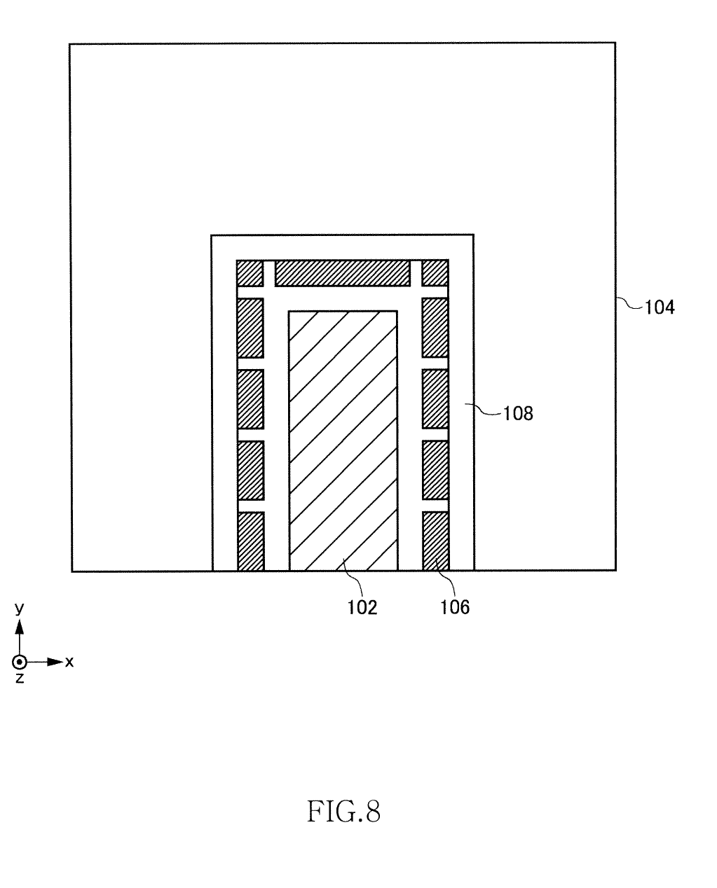

FIG. 8 is a layout diagram showing a second margin region 108 in the partial region P1. The second margin region 108 is set outside the dummy patterns 106. This margin region 108 constitutes a margin region between dummy patterns. The margin region 108 of FIG. 3 and the margin region 108 of FIG. 8 may, but need not, have the same width.

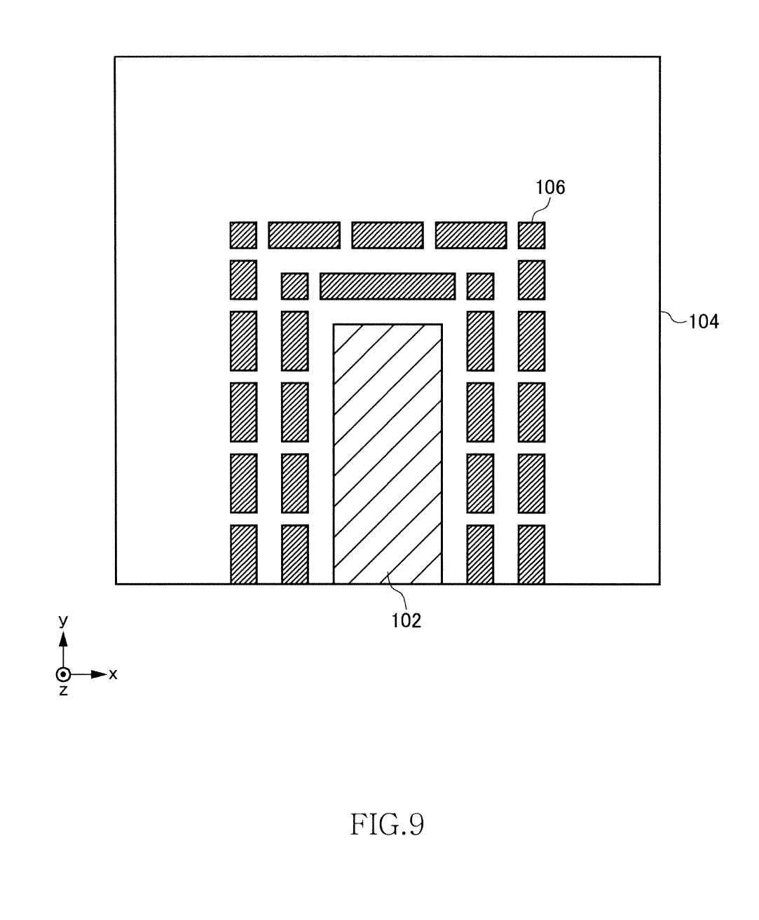

FIG. 9 is a layout diagram showing a second layer of dummy patterns 106 in the partial region P1. A dummy region 110 is further set outside the second margin region 108. Dummy patterns 106 are arranged again in the dummy region 110. The method of arrangement is the same as described in conjunction with FIG. 5. In the same manner, margin regions 108 and dummy regions 110 (dummy patterns 106) are alternately arranged around the wiring pattern 102.

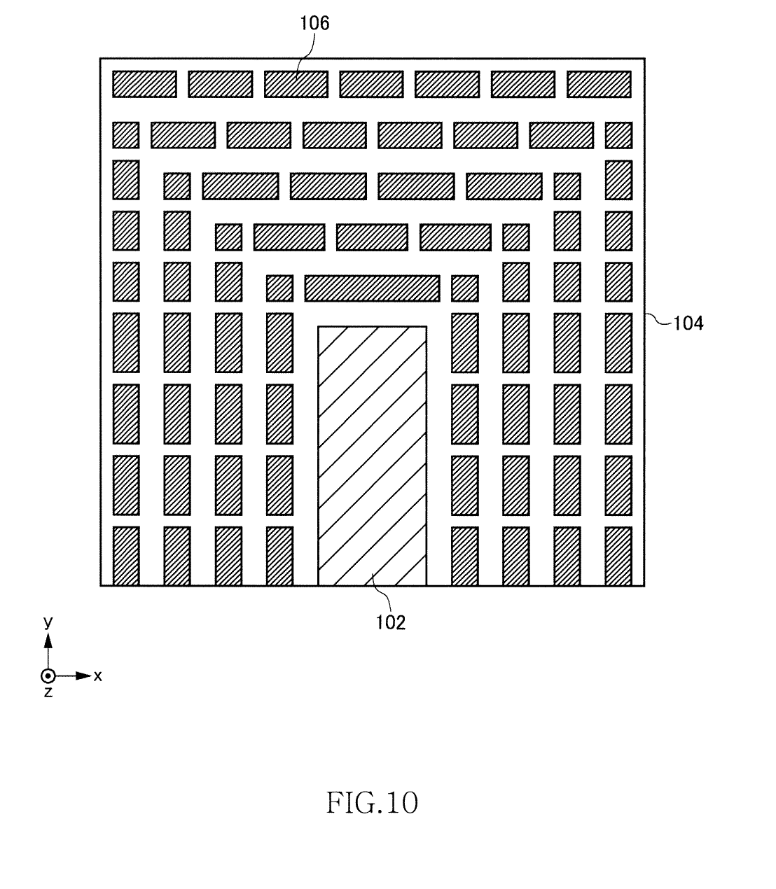

FIG. 10 is an overall layout diagram of dummy patterns 106 in the partial region P1. As has been described in conjunction with FIGS. 2 to 9, margin regions 108 and dummy regions 110 are alternately arranged in the vicinity of the wiring pattern 102. The non-wiring region is thus filled with margin regions 108 and dummy regions 110. As shown in FIG. 10, the dummy patterns 106 are arranged in a radial pattern when seen from the wiring pattern 102. Consequently, the dummy patterns 106 can be laid out in the non-wiring region in a uniform pattern at high density. Because the dummy patterns 106 are not electrically connected to other patterns, the dummy patterns 106 are electrically in a floating state.

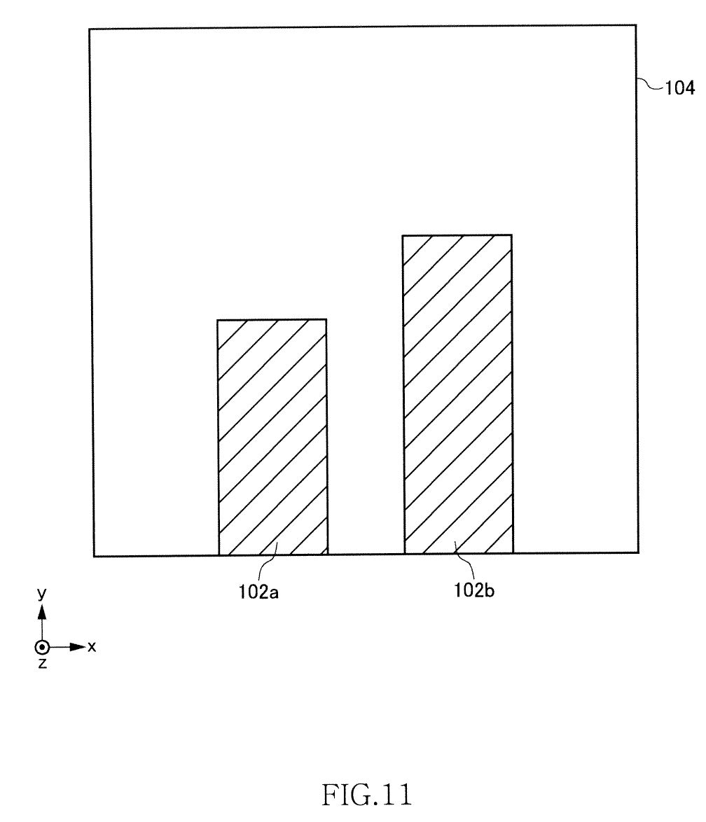

FIG. 11 is a layout diagram showing wiring patterns 102 in the partial region P2. The partial region P2 includes two wiring patterns 102a and 102b both of which extend in the y direction. The wiring pattern 102a and the wiring pattern 102b are close to each other.

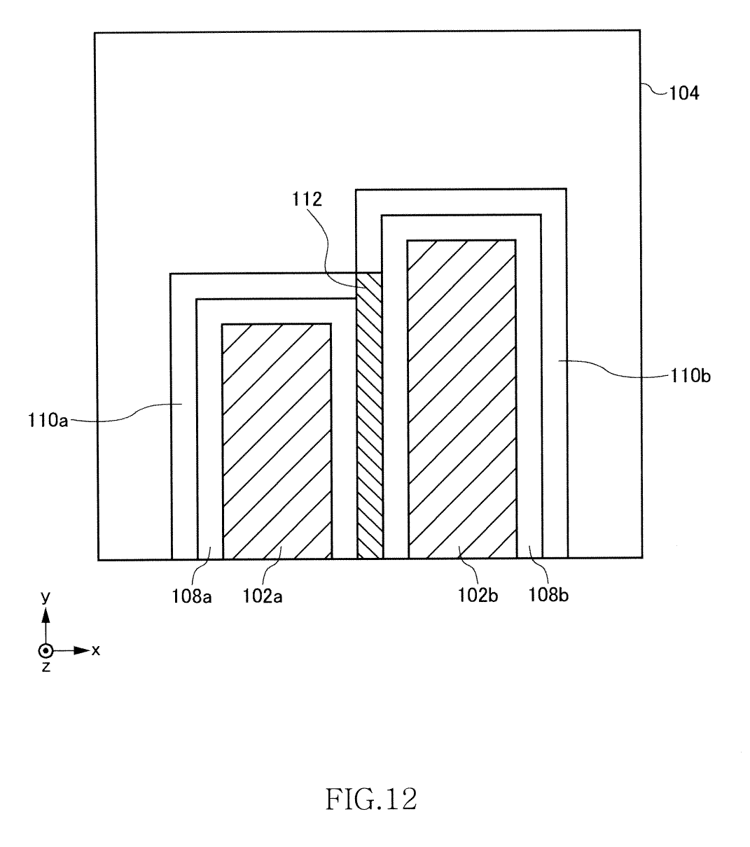

FIG. 12 is a layout diagram showing margin regions 108 and dummy regions 110 in the partial region P2. Like FIG. 3, margin regions 108a and 108b are set around the wiring patterns 102a and 102b, respectively. Dummy regions 110a and 110b are then set around the margin regions 108a and 108b, respectively. In the partial region P2, the dummy regions 110a and 110b overlap each other since the wiring patterns 102a and 102b are close to each other. The overlapping portions will be referred to as an “overlapping region 112.”

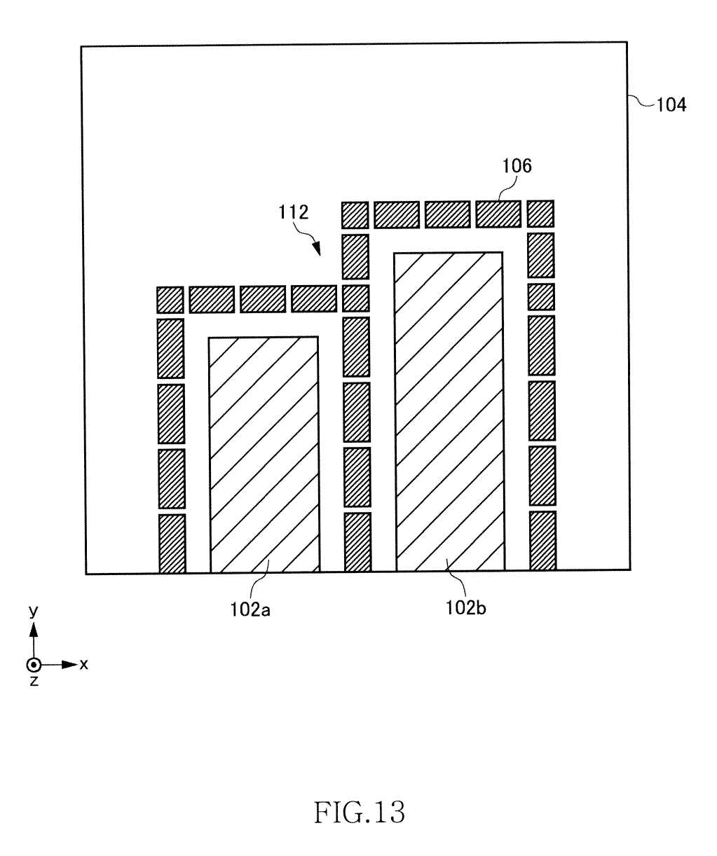

FIG. 13 is a layout diagram showing dummy patterns 106 in the partial region P2. In the partial region P2, the dummy regions 110a and 110b are connected. In other words, the overlapping region 112 is a dummy region shared by the dummy regions 110a and 110b. For such connected dummy regions 110a and 110b, dummy patterns 106 are set by the same method as described in conjunction with FIGS. 5 to 7. Margin regions 108 and dummy regions 110 are alternately arranged further around the dummy patterns 106.

If margin regions 108 overlap instead of dummy regions 110, the overlapping portions of the margin regions 108 may be connected.

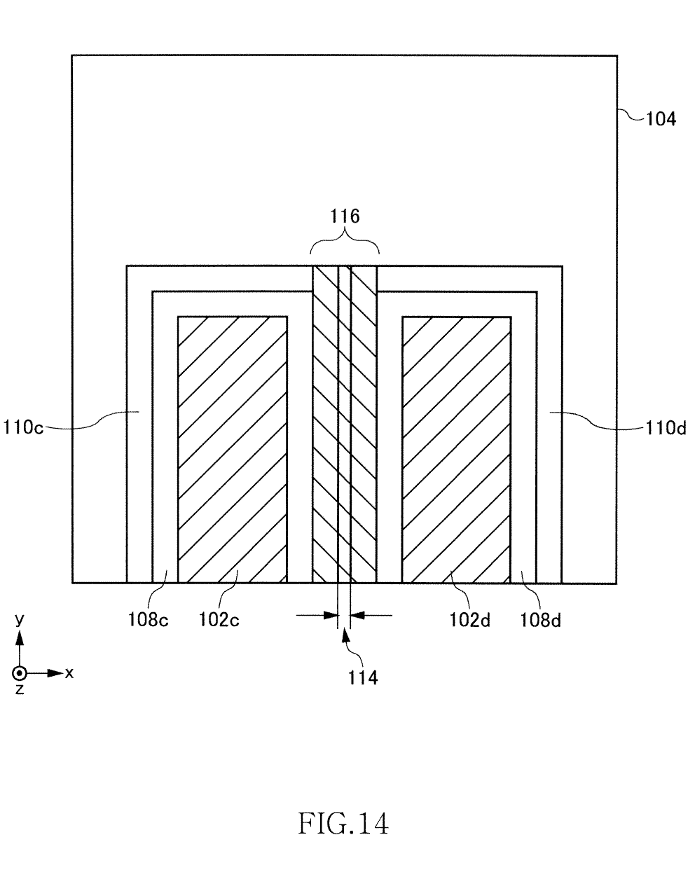

FIG. 14 is a layout diagram showing wiring patterns 102, margin regions 108, and dummy regions 110 in the partial region P3. The partial region P3 also includes two wiring patterns 102c and 102d both of which extend in the y direction. The wiring patterns 102c and 102d are close to each other, but not as close as the wiring patterns 102a and 102b are in the partial region P2.

Margin regions 108c and 108d are set around the wiring patterns 102c and 102d. Dummy regions 110c and 110d are further set around the margin regions 108c and 108d. In the partial region P3, the dummy regions 110c and 110d do not overlap. There is a narrow margin 114 between the dummy regions 110c and 110d. The part of the partial region P3 where the dummy regions 110c and 110d adjoin each other across the margin 114 of smaller than or equal to a predetermined threshold will be referred to as a “proximity region 116.” The threshold may be an arbitrary value. For example, the threshold may be set to a resolution limit value.

The dummy region 110c intended for the wiring pattern 102a and the dummy region 110d intended for the wiring pattern 102b are connected to each other in the proximity region 116. In other words, the proximity region 116 is a dummy region shared by the dummy regions 110c and 110d.

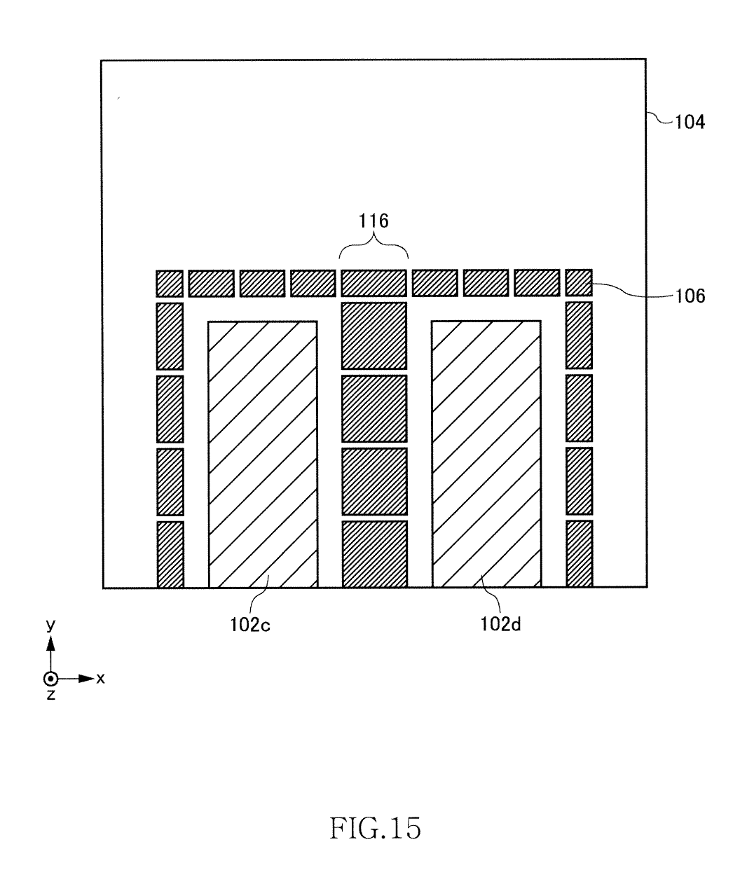

FIG. 15 is a layout diagram showing dummy patterns 106 in the partial region P3. In the partial region P3, the dummy regions 110c and 110d are connected in the proximity region 116. Dummy patterns 106 are arranged in the connected dummy regions 110c and 110d. Margin regions 108 and dummy regions 110 are alternately arranged further around the dummy patterns 106.

If margin regions 108 lie close to each other instead of dummy regions 110, the adjoining portions of the margin regions 108 may be connected.

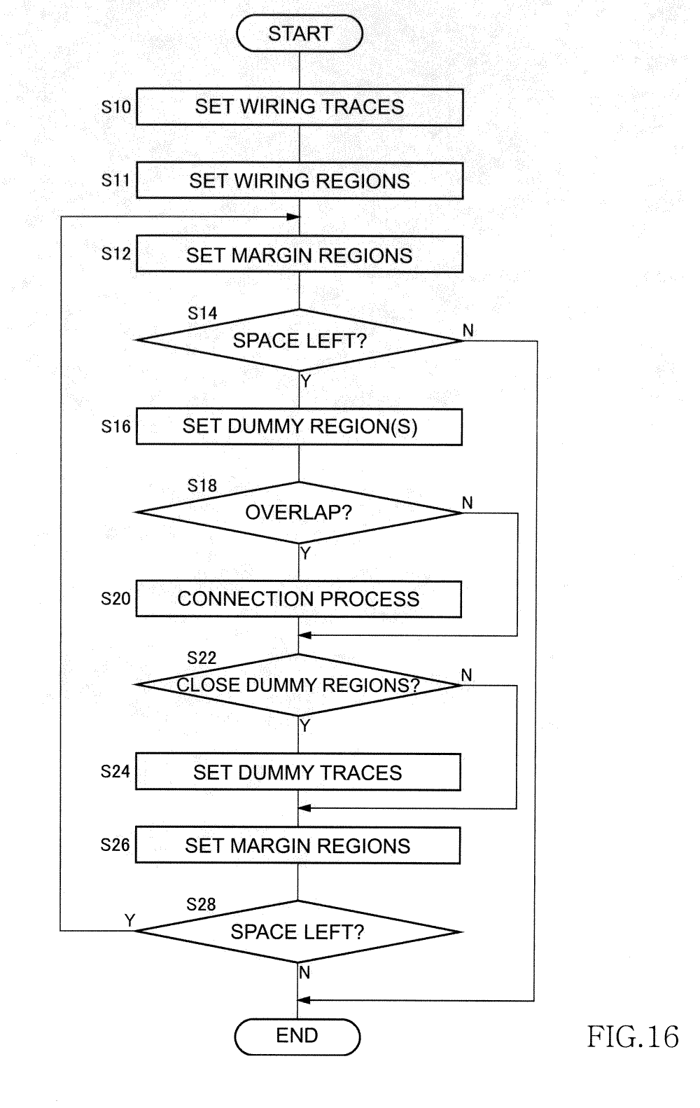

FIG. 16 is a flowchart showing the procedure for designing dummy patterns 106. A designer determines the layout of wiring patterns 102 and dummy patterns 106 on the semiconductor substrate 104 by using design software (semiconductor device design support program) which is installed on a personal computer or the like. In the present embodiment, the designer initially determines the layout of wiring patterns 102 (S10). Next, the designer specifies wiring regions (S11). The rest of the regions are non-wiring regions. S10 and S11 are manual operations. The processing of S12 and subsequent steps is automatically performed. Functions to be described below are implemented as functions of this semiconductor device design support program.

Initially, margin regions 108 are set around all the wiring patterns 102 (S12). If there is no space left to set a dummy region 110 around any margin region 108 (N in S14), the processing ends. If there is a space left (Y in S14), a dummy region(s) 110 is set around the margin region 108 (S16).

If dummy regions 110 overlap at least in part (Y in S18), the dummy regions 110 are connected as described in conjunction with FIGS. 12 and 13 (S20). If no dummy regions 110 overlap (N in S18), S20 is skipped.

If a margin 114 between adjoining dummy regions 110 is smaller than or equal to a predetermined threshold, i.e., if there is any proximity region 116 (Y in S22), the dummy regions 110 are connected as described in conjunction with FIGS. 14 and 15 (S24). If there is no proximity region 116 (N in S22), S24 is skipped.

Dummy patterns 106 are set for the dummy regions 110 set thus (S26). If there is still a space left to set a margin region 108 for any dummy region 110 (Y in S28), the processing returns to S12 to set margin regions 108 again. If there is no space left (N in S28), the processing ends. Margin regions 108 and dummy regions 110 are alternately set with respect to the wiring patterns 102 (wiring regions) until the non-wiring regions are completely filled up.

A method of layout of dummy patterns 106 has been described so far based on the embodiment. According to the present embodiment, dummy patterns 106 can be easily arranged in a uniform pattern at high density in non-wiring regions. Overlapping portions and adjoining portions of dummy regions 110 can be appropriately connected to facilitate adaptation to various wiring patterns 102. In particular, adjoining portions of dummy regions 110 can be connected to prevent margin regions 108 from becoming excessively narrow. In addition, all the dummy patterns 106 can be formed in rectangular or square shapes in the x and y directions. The absence of a need for oblique or specially-shaped dummy patterns 106 has the advantage of high manufacturability.

The present invention has been described so far in conjunction with an embodiment thereof. Such an embodiment has been given by way of illustration. It will be understood by those skilled in the art that various modifications and alterations may be made within the scope of claims of the present invention, and such modifications and alterations are also embraced within the scope of claims of the present invention. The description of the specification and the drawings are therefore to be considered exemplary, not restrictive.

In addition, while not specifically claimed in the claim section, the applicant reserves the right to include in the claim section of the application at any appropriate time the following design methods:

A1. A design method of a semiconductor device, the method comprising:

defining a wiring region on which a wiring pattern is to be formed;

defining a margin region around the wiring region;

defining a dummy region around the margin region; and

arranging a plurality of dummy patterns on the dummy region along an extending direction of the dummy region.

A2. The design method of the semiconductor device as described in A2, wherein the margin region has a substantially constant width between the wiring region and the dummy region.

A3. The design method of the semiconductor device as described in A1, further comprising connecting, when a first dummy region provided corresponding to a first wiring pattern and a second dummy region provided corresponding to a second wiring pattern overlap each other, overlapping portions of the first and second dummy regions into a shared dummy region.

A4. The design method of the semiconductor device as described in A1, further comprising connecting, when a first dummy region provided corresponding to a first wiring pattern and a second dummy region provided corresponding to a second wiring pattern adjoin each other with a space smaller than or equal to a threshold therebetween, adjoining portions of the first and second dummy regions into a shared dummy region including the space.

What is claimed is:

1. A semiconductor device comprising:
a wiring pattern formed on a wiring region;
a dummy pattern formed on a dummy region; and
a margin region being free from the wiring pattern and the dummy pattern, the margin region having a substantially constant width between the wiring region and the dummy region.

2. The semiconductor device as claimed in claim 1, wherein a plurality of the dummy patterns are arranged on an extending direction of the dummy region.

3. The semiconductor device as claimed in claim 2, wherein at least two of the dummy patterns have different shapes from each other.

4. The semiconductor device as claimed in claim 2, wherein
the dummy region has a first region extending in a first direction, a second region extending in a second direction different from the first direction, and a corner portion overlapping the first and second region, and
one of the dummy patterns is arranged on the corner portion of the dummy region.

5. The semiconductor device as claimed in claim 2, wherein the dummy patterns have a rectangular shape in which a longitudinal direction thereof is arranged in the extending direction.

6. The semiconductor device as claimed in claim 2, wherein
the wiring pattern includes first and second wiring patterns extending in parallel,
the margin region includes first and second margin regions each surrounding corresponding one of the first and second wiring patterns, and
at least one of the dummy patterns is provided between the first and second margin regions.

7. The semiconductor device as claimed in claim 6, wherein the at least one of the dummy patterns that is provided between the first and second margin regions has a width wider than twice as wide as other of the dummy patterns and narrower than sum of twice as wide as other of the dummy patterns and the constant width of the margin region.

8. The semiconductor device as claimed in claim 1, wherein a plurality of the margin regions and a plurality of the dummy regions are alternately formed around the wiring pattern.

9. A semiconductor device comprising:
a wiring pattern to transfer a signal or to be supplied with a specific voltage and including a first edge and a second edge intersect with the first edge;
a plurality of first patterns provided along to the first edge and aligned in a first straight line;
a plurality of second patterns provided along to the second edge and aligned in a second straight line; and
a third pattern of a regular tetragon formed on an intersection of the first and second straight lines.

10. The semiconductor device according to claim 9, wherein the shape of at least one of the first patterns is different from the third pattern.

11. The semiconductor device according to claim 9, further comprising a plurality of fourth patterns provided to a third edge in parallel with the first edge and aligned in a third straight line, a width of at least one of the plurality of fourth patterns being lager than that of the plurality of first patterns.

12. The semiconductor device according to claim 9, wherein the plurality of first patterns and the plurality of second patterns formed by a metal.

13. The semiconductor device according to claim 9, wherein each of the plurality of first patterns and the plurality of second patterns is in an electrically floating state.
